(19) United States
(12) Patent Application Publication
(10) Pub. No.: US 2013/0322048 A1
(43) Pub. Date: Dec. 5, 2013

(54) FIXING MECHANISM AND ELECTRONIC DEVICE USING THE SAME

(71) Applicants: Hong Fu Jin Precision Industry (ShenZhen) Co., Ltd., (US); HON HAI PRECISION INDUSTRY CO., LTD., New Taipei (TW)

(72) Inventors: XUE-FENG WAN, Shenzhen (CN); PING LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/744,469

(22) Filed: Jan. 18, 2013

(30) Foreign Application Priority Data
Jun. 5, 2012 (CN) 201220261460.6

(51) Int. Cl. H05K 9/00; H05K 7/14

(52) U.S. Cl. CPC H05K 9/0007; H05K 7/14
USPC 361/818; 24/704.1

(57) ABSTRACT

An electronic device includes a housing, an electromagnetic shield and a fixing mechanism for securing the electromagnetic shield to the housing. The fixing mechanism includes a first fixing component. The first fixing component includes a first post and two first fixing elements. Free ends of the two first fixing elements are opposite to each other and protrude out of a surface of the electromagnetic shield opposite to the housing. The first post extends through the first fixing hole and is clipped by the free ends of the first fixing elements, for preventing the electromagnetic shield from disengaging from the housing in a first orientation.

### BACKGROUND

1. Technical Field

The present disclosure relates to electronic devices; and particularly, to an electronic device having a fixing mechanism.

2. Description of Related Art

Electronic devices, such as disc players, notebook computers, include a housing having a post, a plurality of electronic components and at least one electromagnetic shield. The electronic components are received in the housing. The electromagnetic shield is secured to the housing, for reducing electromagnetic interference caused by the electronic components. Generally, the electromagnetic shield defines a hole for engaging with the post to secure the electromagnetic shield to the housing. However, when the size of the hole is larger than the size of the post, the electromagnetic shield may become loose; when the size of the hole is smaller than the size of the post, the electromagnetic shield may be deformed.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partially disassembled view of an embodiment of an electronic device.

FIG. 2 is a partially assembled view of the electronic device of FIG. 1.

FIG. 3 is an enlarged view of label III of the electronic device of FIG. 2.

### DETAILED DESCRIPTION

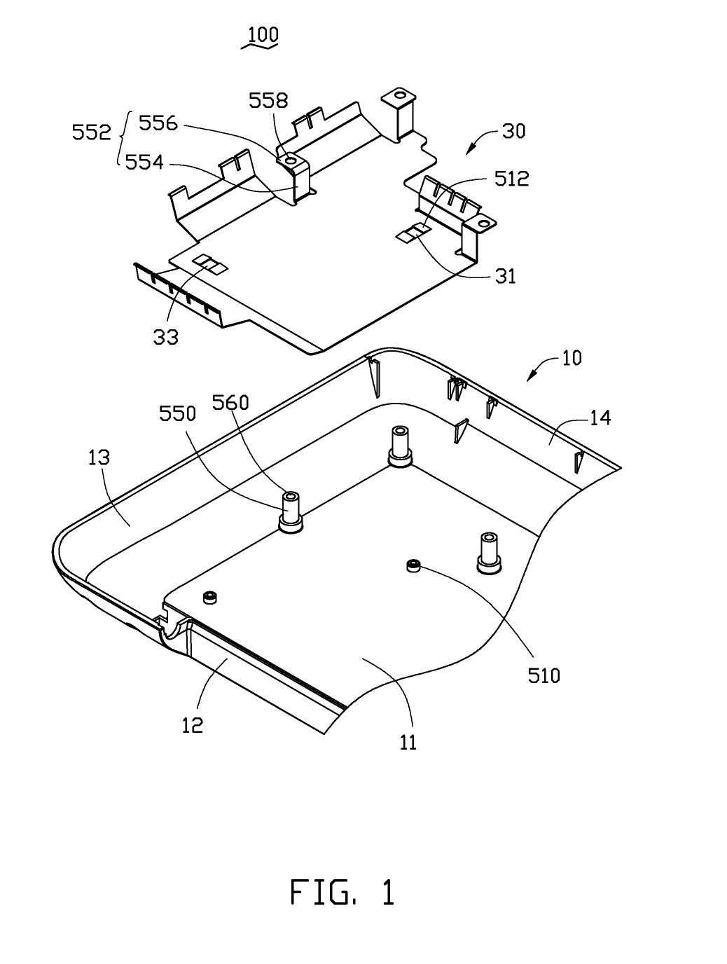

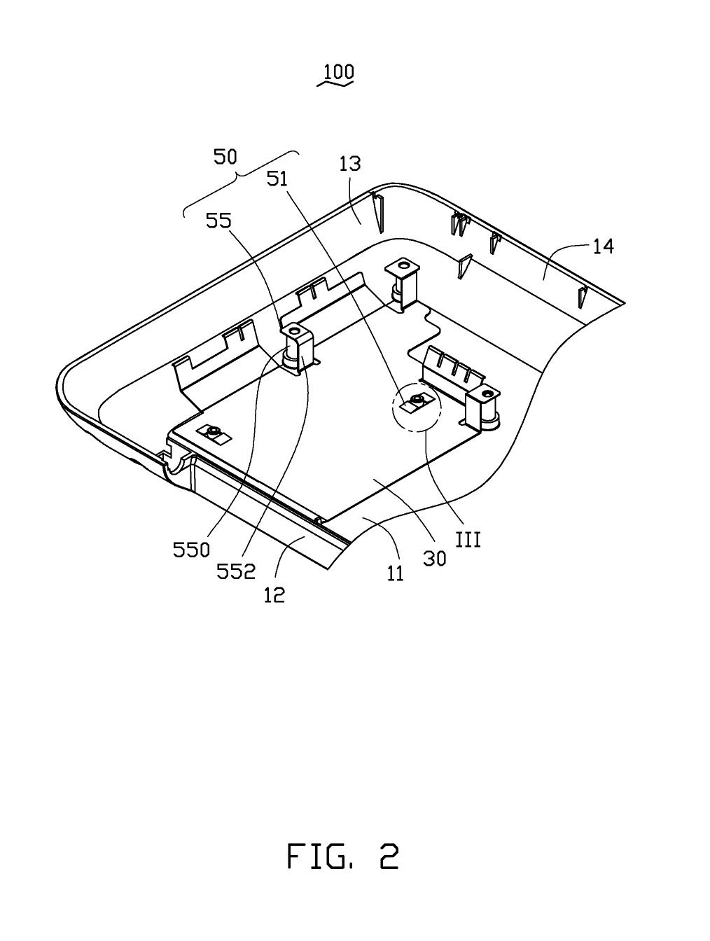

Referring to FIG. 1, an electronic device 100 includes a housing 10, an electromagnetic shield 30 for covering an electronic components (not shown), and a fixing mechanism 50 (see FIG. 2). The electromagnetic shield 30 is secured to the housing 10 via the fixing mechanism 50 and is used for reducing electromagnetic interference caused by the electronic component. The electronic device 100 may be a disc player, a notebook computer, or other electronic devices. In the embodiment, the electronic device 100 is a disc player.

The housing 10 is substantially rectangular, and includes a bottom plate 11, a first sidewall 12, a second sidewall 13, a third sidewall 14 opposite to the first sidewall 12 and a fourth sidewall (not shown) opposite to the second sidewall 13. The first, second, third and fourth sidewalls 12, 13, 14 slantingly extend from four rims of the bottom plate 11 and interconnect with each other.

The electromagnetic shield 30 is substantially plate-shaped, and is secured to an inner surface of the bottom plate 11. The electromagnetic shield 30 defines a rectangular first fixing hole 31 and a rectangular second fixing hole 33. The first fixing hole 31 extends in a first direction perpendicular to the first sidewall 12. The second fixing hole 33 is spaced apart from the first fixing hole 31 and extends in a second direction parallel to the second sidewall 13.

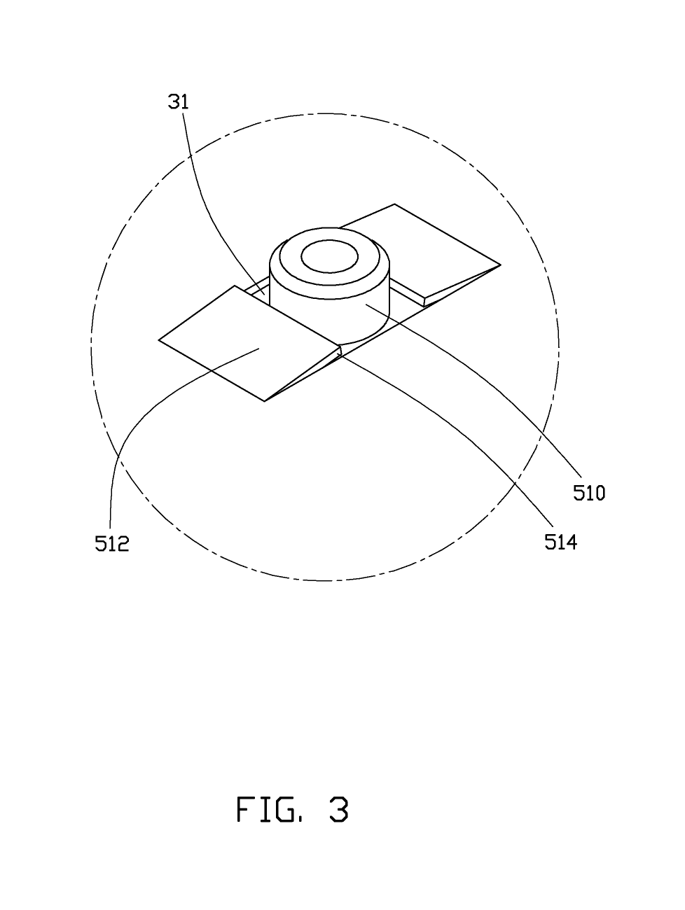

Referring to FIGS. 2 and 3, the fixing mechanism 50 includes two first fixing components 51 and a plurality of second fixing components 55 which are spaced from each other.

Each first fixing component 51 includes a columnar shaped first post 510 and two first fixing elements 512. The first posts 510 protrude in its entirety from the inner surface of the bottom plate 11, with one first post 510 corresponding to the first fixing hole 31 and another first posts 510 corresponding to the second fixing hole 33. The first fixing elements 512 are made of elastic material. Two first fixing elements 512 of one first fixing component 51 are outwardly curved from opposite edges of the first fixing hole 31 and extend along a direction perpendicular to the first sidewall 12. The free ends 514 of the two first fixing elements 512 are opposite to each other and protrude out of a surface of the electromagnetic shield 30 opposite to the bottom plate 11. Two first fixing elements 512 of another first fixing component 51 are outwardly curved from opposite edges of the second fixing hole 33 and extend along a direction parallel to the first sidewall 12. The free ends 514 of the two first fixing elements 512 are opposite to each other and protrude out of a surface of the electromagnetic shield 30 opposite to the bottom plate 11. The width of a gap between the free ends 514 of the corresponding first fixing elements 512 is smaller than the size of the corresponding first post 51.

Each second fixing component 55 is made of rigid material, and includes a columnar shaped second post 550 and a second fixing element 552 engaging with the second post 550. The second fixing element 552 protrudes from a rim of the electromagnetic shield 30, and includes a first connection portion 554 and a second connection portion 556. The first connection portion 554 perpendicularly extends from the electromagnetic shield 30. The second connection portion 556 perpendicularly extends from an end of the first connection portion 554 opposite to the electromagnetic shield 30. The second connection portion 556 defines a third fixing hole 558. The second post 550 protrudes from the inner surface of the bottom plate 11, and defines a fourth fixing hole 560 opposite to the electromagnetic shield 30. The vertical height of the second post 550 is equal to the distance between the second connection portion 556 and the inner surface of bottom plate 11. In other embodiment, the number and position of the first and second fixing portions 51 and 55 can be changed according to need. The curve direction of the first fixing elements 512 relative to the electromagnetic shield 30 also can be changed as needed. For example, the first fixing elements 512 can be upwardly curved from the corresponding edges of the second fixing hole 33.

To secure the electromagnetic shield 30 to the bottom plate 11, firstly, the first posts 510 respectively extend through the first and second fixing holes 31, 33 and depress the corresponding first fixing elements 512. The first fixing elements 512 are elastically deformed to allow the first posts 510 being clipped by the corresponding free ends 514 of the first fixing elements 512. Thus, the first fixing elements 512 resist opposite ends of the first fixing posts 510 respectively, and the first posts 510 are further restricted between opposite edges of the first and second fixing hole 31, 33 respectively, for preventing the electromagnetic shield 30 from disengaging from the bottom plate 11 in a first orientation parallel to the bottom plate 11. Secondly, the second post 550 resists against a surface of the second connection portion 556, with the fourth fixing hole 560 aligned to the third fixing hole 558. A fixing component (e.g., a screw) extends through the third and fourth fixing holes 558, 560 to fix the electromagnetic shield 30 to the bottom plate 11, for preventing the electromagnetic shield 30 from disengaging from the bottom plate 11 in a second orientation perpendicular to the bottom plate 11.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing;
an electromagnetic shield fixed to the housing and defining a first fixing hole; and
a fixing mechanism for securing the electromagnetic shield to the housing, the fixing mechanism comprising:
at least one first fixing component, each first fixing component comprising a first post and two first fixing elements; the first post protruding from the housing and corresponding to the at least one first fixing hole, the two first fixing elements extending from opposite edges of the corresponding first fixing hole;
wherein free ends of the two first fixing elements are opposite to each other and protrude out of a surface of the electromagnetic shield opposite to the housing, the first post extends through the corresponding first fixing hole and is clipped by the free ends of the corresponding first fixing elements, for preventing the electromagnetic shield from disengaging from the housing in a first orientation.

2. The electronic device as claimed in claim 1, wherein the fixing mechanism comprises a second fixing component, the second fixing component comprises a second post and a second fixing element; the second fixing element protrudes from a rim of the electromagnetic shield, the second post protrudes from the housing; the second post is secured to the second fixing element, for preventing the electromagnetic shield from disengaging from the housing in a second orientation perpendicular to the first orientation.

3. The electronic device as claimed in claim 2, wherein the second fixing component comprises a first connection portion and a second connection portion, the first connection portion protrudes from a rim of the electromagnetic shield, the second connection portion extends from an end of the first connection portion for engaging with the second post.

4. The electronic device as claimed in claim 3, wherein the vertical height of the second post is equal to the distance between the second connection portion and a surface of the housing opposite to the electromagnetic shield.

5. The electronic device as claimed in claim 1, wherein the electromagnetic shield further defines at least one second fixing hole, the at least one first fixing hole extends in a first direction, and the at least one second fixing hole extends in a second direction perpendicular to the first direction; two first fixing elements are outwardly curved from opposite edges of the corresponding first fixing hole in the first direction and are opposite to each other, and two first fixing elements are outwardly curved from opposite edges of the corresponding second fixing hole in the second direction and are opposite to each other, for clipping the corresponding first post in the first and second directions and preventing the electromagnetic shield from disengaging from the housing in the first orientation.

6. The electronic device as claimed in claim 1, wherein the width of a gap between the free ends of the corresponding first fixing elements is smaller than the size of the first post.

7. The electronic device as claimed in claim 1, wherein the second fixing element is made of rigid material.

8. The electronic device as claimed in claim 1, wherein the first fixing elements are made of elastic material.

9. A fixing mechanism for securing an electromagnetic shield to a housing of an electronic device, the electromagnetic shield defining at least one first fixing hole, the fixing mechanism comprising:
at least one first fixing component, each first fixing component comprising a first post and two first fixing elements; the first post protruding from the housing and corresponding to the at least one first fixing hole, the two first fixing elements extending from opposite edges of the first fixing hole;
wherein free ends of the two first fixing elements are opposite to each other and protrude out of a surface of the electromagnetic shield opposite to the housing, the first post extends through the corresponding first fixing hole and is clipped by the free ends of the corresponding first fixing elements, for preventing the electromagnetic shield from disengaging from the housing in a first orientation.

10. The fixing mechanism as claimed in claim 9, wherein the fixing mechanism comprises a second fixing component, the second fixing component comprises a second post and a second fixing element; the second fixing element protrudes from a rim of the electromagnetic shield, the second post protrudes from the housing; the second post is secured to the second fixing element, for preventing the electromagnetic shield from disengaging from the housing in a second orientation perpendicular to the first orientation.

11. The fixing mechanism as claimed in claim 10, wherein the second fixing component comprises a first connection portion and a second connection portion, the first connection portion protrudes from a rim of the electromagnetic shield, the second connection portion extends from an end of the first connection portion for engaging with the second post.

12. The fixing mechanism as claimed in claim 11, wherein the vertical height of the second post is equal to the distance between the second connection portion and a surface of the housing opposite to the electromagnetic shield.

13. The fixing mechanism as claimed in claim 9, wherein the electromagnetic shield further defines at least one second fixing hole, the at least one first fixing hole extends in a first direction, and the at least one second fixing hole extends in a second direction perpendicular to the first direction; two first fixing elements are outwardly curved from opposite edges of the corresponding first fixing hole in the first direction and are opposite to each other, and two first fixing elements are outwardly curved from opposite edges of the corresponding second fixing hole in the second direction and are opposite to each other, for clipping the corresponding first post in the first and second directions and preventing the electromagnetic shield from disengaging from the housing in the first orientation.

14. The electronic device as claimed in claim 9, wherein the width of a gap between the free ends of the corresponding first fixing elements is smaller than the size of the first post.

15. The electronic device as claimed in claim 9, wherein the second fixing element is made of rigid material.

16. The electronic device as claimed in claim 9, wherein the first fixing elements are made of elastic material.
